(19) United States
(12) Patent Application Publication
(10) Pub. No.: US 2018/0114760 A1
(43) Pub. Date: Apr. 26, 2018

(54) Package Substrate and Fabrication Method Thereof, and Integrated Circuit Chip

(71) Applicant: Huawei Technologies Co., Ltd., Shenzhen (CN)

(72) Inventors: HuiLi Fu, Shenzhen (CN); Jianwei Guo, Shenzhen (CN); Tiejun Liu, Shenzhen (CN)

(21) Appl. No.: 15/792,307

(22) Filed: Oct. 24, 2017

(30) Foreign Application Priority Data
Oct. 24, 2016 (CN) 201610937783.5

(51) Int. Cl. H01L 23/00; H01L 23/498; H01L 21/48; H01L 23/31; H01L 23/66

(52) U.S. Cl. CPC H01L 23/562; H01L 23/49822; H01L 23/49838; H01L 23/49894; H01L 2224/16227; H01L 24/16; H01L 23/3185; H01L 23/66; H01L 21/4857

(57) ABSTRACT

A package substrate, including a first reference layer and a second reference layer disposed opposite to each other, a first composite layer disposed on a side of the first reference layer and close to the second reference layer, a second composite layer disposed on a side of the second reference layer and close to the first reference layer, and a metal trace is laminated between the first composite layer and the second composite layer. The first composite layer and the second composite layer each include a first dielectric layer and a second dielectric layer disposed opposite to and in contact with each other, the first dielectric layer is in contact with the metal trace, and a stiffness of the second dielectric layer is greater than a stiffness of the first dielectric layer.

### CROSS-REFERENCE TO RELATED APPLICATION

This application claims priority to Chinese Patent Application No. 201610937783.5 filed on Oct. 24, 2016, which is hereby incorporated by reference in its entirety.

### TECHNICAL FIELD

The present disclosure relates to the field of communications technologies, and in particular, to a package substrate and a fabrication method thereof, and an integrated circuit (IC) chip.

### BACKGROUND

A package substrate is a motherboard for manufacturing an IC chip or a printed circuit board (PCB).

As shown in FIG. 1, the package substrate is formed by a conductive reference layer 11 and a non-conductive dielectric layer 12 that are stacked alternately. A signal circuit is laminated inside the dielectric layer 12. The signal circuit is generally formed by one or more metal traces 13. The reference layer 11 is generally configured to carry a power supply or ground signal. A signal carried in each metal trace 13 is eventually led to each input/output (I/O) interface of the IC chip or the PCB.

However, a higher speed or frequency of a signal brings severer attenuation of the signal being transmitted on the metal trace 13, and causes a larger link loss. Generally, the link loss can be reduced by increasing a width of the metal trace 13, but a change in the trace width causes a change in impedance of the metal trace 13. To ensure that the impedance remains unchanged, a thickness of the dielectric layer 12 needs to be designed according to a signal speed. As shown in FIG. 2, one dielectric layer 12 is used as an example. When the signal speed is higher, a width D of the metal trace 13 is larger, and a thickness L of the dielectric layer 12 is also larger.

However, because a mechanical property of a material for fabricating the dielectric layer 12 is relatively poor, it is difficult to produce a dielectric layer 12 with a large thickness. When the thickness L of the dielectric layer 12 is increased to an extent, a technique process limit is reached. In this case, the thickness of the dielectric layer 12 cannot be further increased, and the link loss cannot be reduced.

### SUMMARY

Embodiments of the present disclosure provide a package substrate and a fabrication method thereof, and an IC chip in order to reduce a link loss generated when a high frequency signal or a high-speed signal is being transmitted in the package substrate.

To achieve the foregoing objective, the following technical solutions are used in the embodiments of the present disclosure.

According to a first aspect, an embodiment of the present disclosure provides a package substrate, including a first reference layer and a second reference layer that are disposed opposite to each other, a first composite layer is disposed on a side that is of the first reference layer and close to the second reference layer, a second composite layer is disposed on a side that is of the second reference layer and close to the first reference layer, and a metal trace is laminated between the first composite layer and the second composite layer, and the first composite layer and the second composite layer each include a first dielectric layer and a second dielectric layer that are disposed opposite to and in contact with each other, the first dielectric layer is in contact with the metal trace, and stiffness of the second dielectric layer is greater than stiffness of the first dielectric layer. That is, different from a conventional arrangement of a single dielectric layer enclosing a metal trace, in the package substrate provided in the embodiments of the present disclosure, the metal trace is laminated between the first composite layer and the second composite layer, and each composite layer includes the first dielectric layer and the second dielectric layer that are respectively made of two types of dielectrics. In both composite layers, the first dielectric layer with relatively small stiffness is in contact with the metal trace such that the metal trace is enclosed by the first dielectric layers using a lamination technique. The second dielectric layer with relatively large stiffness is disposed on a side that is of the first dielectric layer and away from the metal trace. The second dielectric layer has relatively large stiffness and is not easy to deform. Therefore, a second dielectric layer with a relatively large thickness can be produced. In this case, for a high frequency signal or a high-speed signal, a conductor loss generated during signal transmission may be reduced by increasing a thickness of the second dielectric layer in addition to increasing a width of the metal trace, thereby reducing a link loss throughout the transmission.

In a possible design manner, a dielectric loss factor of the first dielectric layer is less than a dielectric loss factor of the second dielectric layer. A smaller dielectric loss factor of a dielectric layer results in a smaller dielectric loss generated when a signal is being transmitted at the dielectric layer. In this case, when the dielectric loss factor of the first dielectric layer is less than the dielectric loss factor of the second dielectric layer, a dielectric loss generated when a signal on the metal trace is being transmitted at the first dielectric layer can be reduced because the metal trace is enclosed by the first dielectric layer in the first composite layer and the first dielectric layer in the second composite layer. That is, the package substrate provided in the embodiments of the present disclosure can not only reduce the conductor loss generated during signal transmission, but also reduce the dielectric loss generated during signal transmission.

In a possible design manner, the first composite layer and the second composite layer each further include a third dielectric layer disposed on a side that is of the second dielectric layer and away from the first dielectric layer, where a mechanical property of a material of the third dielectric layer is the same as a mechanical property of a material of the first dielectric layer.

In a possible design manner, the material of the third dielectric layer is the same as the material of the first dielectric layer, and a thickness of the third dielectric layer is equal to a thickness of the first dielectric layer. In this case, the first composite layer and the second composite layer each can be regarded as a “sandwich structure” in which the first dielectric layer and the third dielectric layer sandwich the second dielectric layer. In the “sandwich structure,” when the first dielectric layer and the third dielectric layer with the same material are respectively disposed on two sides of the second dielectric layer for lamination, tension is generated on both a contact surface between the first dielectric layer and the second dielectric layer and a contact surface between the third dielectric layer and the second dielectric layer. In this way, the first dielectric layer and the third dielectric layer are attached on the two sides of the second dielectric layer such that a structurally stable “sandwich structure” is formed in each of the first composite layer and the second composite layer. Therefore, more stable structures of the first composite layer and the second composite layer are formed.

In a possible design manner, a coefficient of thermal expansion (CTE) of the second dielectric layer is less than or equal to 9 part per million (ppm)/Celsius (° C.).

In a possible design manner, a Young's modulus of the second dielectric layer is greater than or equal to 25 megapascals (Mpa).

In a possible design manner, a dielectric loss factor of the first dielectric layer is less than or equal to 0.01.

According to a second aspect, an embodiment of the present disclosure provides a method for fabricating a package substrate, including laminating a first composite layer on a first reference layer, where the first composite layer includes a first dielectric layer and a second dielectric layer that are disposed opposite to each other, stiffness of the second dielectric layer is greater than stiffness of the first dielectric layer, and the first dielectric layer in the first composite layer is away from the first reference layer, forming a metal trace at the first composite layer, laminating a second composite layer on the first composite layer at which the metal trace is formed, where the second composite layer includes a first dielectric layer and a second dielectric layer that are disposed opposite to each other, stiffness of the second dielectric layer is greater than stiffness of the first dielectric layer, and the first dielectric layer in the second composite layer is in contact with the metal trace, and laminating a second reference layer on the second composite layer.

In a possible design manner, before laminating the first composite layer on a first reference layer, the method further includes fabricating the first composite layer and the second composite layer.

In a possible design manner, the first composite layer and the second composite layer each further include a third dielectric layer disposed on a side that is of the second dielectric layer and away from the first dielectric layer, and a material of the third dielectric layer is the same as a material of the first dielectric layer, where fabricating the first composite layer or the second composite layer includes respectively laminating the first dielectric layer and the third dielectric layer onto two sides of the second dielectric layer to obtain the first composite layer or the second composite layer.

In a possible design manner, laminating the first composite layer on a first reference layer includes laminating the first composite layer onto the first reference layer using the third dielectric layer in the first composite layer as a lamination surface, and laminating the second composite layer on the first composite layer at which the metal trace is formed includes laminating, using the first dielectric layer in the second composite layer as a lamination surface, the second composite layer onto the first composite layer at which the metal trace is formed.

According to a third aspect, an embodiment of the present disclosure provides a method for fabricating a package substrate, including performing one-off lamination in a sequence of a first reference layer, a first composite layer, a metal trace, a second composite layer, and a second reference layer in order to form the package substrate, where the first composite layer and the second composite layer each include a first dielectric layer and a second dielectric layer that are disposed opposite to each other, the first dielectric layer is in contact with the metal trace, and stiffness of the second dielectric layer is greater than stiffness of the first dielectric layer.

According to a fourth aspect, an embodiment of the present disclosure provides an IC chip, and the IC chip includes the package substrate.

According to a fifth aspect, an embodiment of the present disclosure provides a PCB, and the PCB includes the package substrate.

In the present disclosure, a name of the package substrate does not set a limitation on devices themselves. In actual implementation, these devices may appear with other names. Provided that their functions are similar to those in the present disclosure, the various devices fall within the scope of the claims of the present disclosure and the equivalents thereof.

In addition, for a technical effect brought by any one of the design manners in the second aspect to the fifth aspect, refer to the technical effect brought by the different design manners in the first aspect. Details are not provided herein.

These aspects or other aspects of the present disclosure are more readily understood in following descriptions of embodiments.

### BRIEF DESCRIPTION OF DRAWINGS

To describe the technical solutions in the embodiments of the present disclosure more clearly, the following briefly describes the accompanying drawings required for describing the embodiments.

FIG. 1 is a schematic structural diagram of a package substrate;

FIG. 2 is a schematic diagram of a principle of reducing a link loss;

FIG. 3 is a schematic diagram of an application scenario of a package substrate according to an embodiment of the present disclosure;

FIG. 4 is schematic structural diagram 1 of a package substrate according to an embodiment of the present disclosure;

FIG. 5 is schematic structural diagram 2 of a package substrate according to an embodiment of the present disclosure;

FIG. 6 is a schematic flowchart of a method for fabricating a package substrate according to an embodiment of the present disclosure;

FIG. 7 is schematic diagram 1 of a technique of a method for fabricating a package substrate according to an embodiment of the present disclosure;

FIG. 8 is schematic diagram 2 of a technique of a method for fabricating a package substrate according to an embodiment of the present disclosure; and

FIG. 9 is schematic diagram 3 of a technique of a method for fabricating a package substrate according to an embodiment of the present disclosure.

### DESCRIPTION OF EMBODIMENTS

The following describes the technical solutions in the embodiments of the present disclosure with reference to the accompanying drawings in the embodiments of the present disclosure. The described embodiments are merely a part rather than all of the embodiments of the present disclosure.

In addition, the terms “first” and “second” are merely intended for a purpose of description, and shall not be understood as an indication or implication of relative importance or implicit indication of the number of indicated technical features. Therefore, a feature limited by “first” or “second” may explicitly or implicitly include one or more features. In the description of the present disclosure, “multiple” means two or more unless otherwise specified.

An embodiment of the present disclosure provides a package substrate, and the package substrate may be used as a motherboard in a structure such as an IC chip or a PCB.

For example, as shown in FIG. 3, FIG. 3 is a cross sectional view of an IC chip. Solder balls 21 are disposed on one side of a package substrate 100. The solder balls 21 may be used as an I/O interface of the IC chip for communication with an external device. A package surface 22 is disposed on the other side of the package substrate 100. A passive component 23 and a wafer 24 may be packaged under the package surface 22.

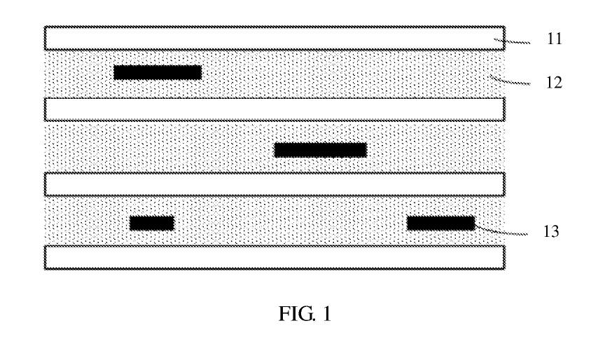

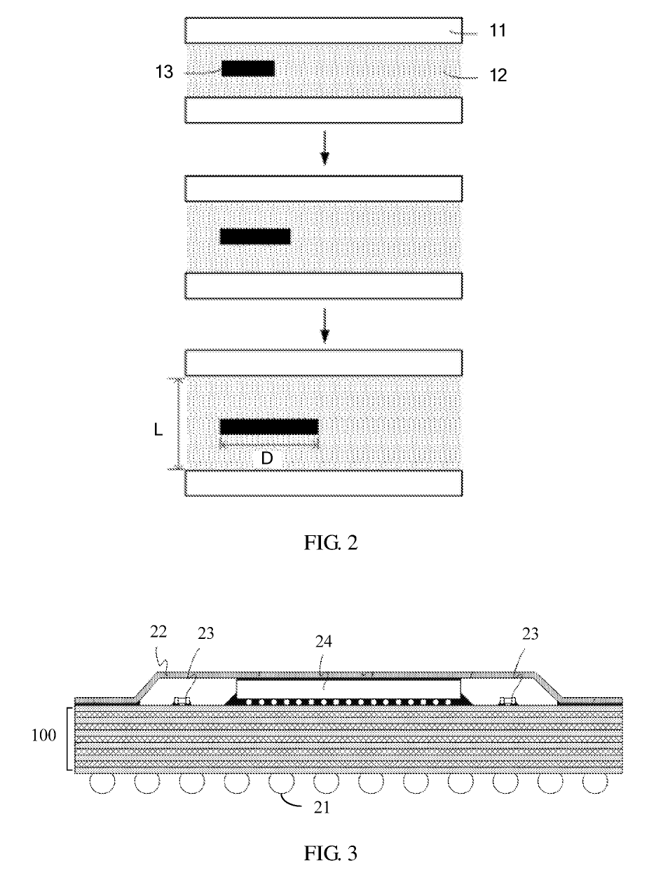

Similar to FIG. 1, the package substrate 100 shown in FIG. 3 is formed by a conductive reference layer and a non-conductive dielectric layer that are stacked alternately. In an IC chip, a signal is generally transmitted on a metal trace in the dielectric layer. A higher speed or frequency of the signal brings severer attenuation of the signal being transmitted on the metal trace. Such a loss caused by the metal trace is referred to as a conductor loss. In addition, the dielectric layer is made of a non-conductive insulating material. In this case, when the signal is being transmitted on the metal trace, the insulating material causes an energy loss inside the dielectric layer due to a hysteresis effect of dielectric conductivity and dielectric polarization under the influence of an electric field. Such a loss caused by the dielectric layer in which the metal trace is located is referred to as a dielectric loss.

That is, a link loss generated when a signal is being transmitted in the package substrate 100 includes a conductor loss and a dielectric loss. A width of the metal trace 13 is inversely proportional to resistance of the metal trace 13. Therefore, the conductor loss is usually reduced by increasing the width of the metal trace. However, after the width of the metal trace is increased, impedance of the metal trace is changed accordingly. Therefore, in addition to the width of the metal trace, a thickness of the dielectric layer also needs to be increased in order to ensure that impedance is consistent before and after the width of the metal trace is changed. The dielectric layer is generally made of a material with relatively good flexibility and is easy to deform during production. Therefore, a dielectric layer with a relatively large thickness cannot be obtained, and an indicator requirement of the link loss generated when a high frequency signal or a high-speed signal is being transmitted in the package substrate 100 cannot be met.

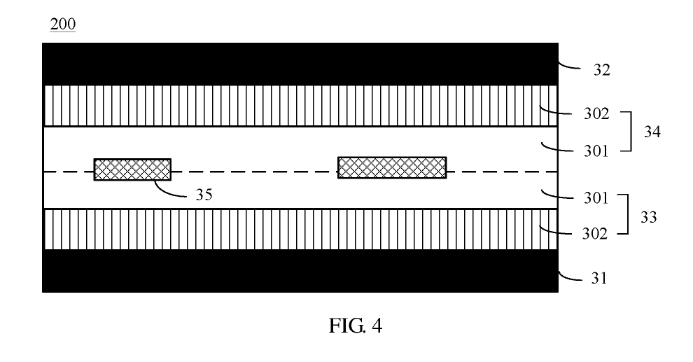

In view of this, an embodiment of the present disclosure provides a package substrate 200 in FIG. 4. As shown in FIG. 4, the package substrate 200 includes a first reference layer 31 and a second reference layer 32 that are disposed opposite to each other. A first composite layer 33 is disposed on a side that is of the first reference layer 31 and close to the second reference layer 32, a second composite layer 34 is disposed on a side that is of the second reference layer 32 and close to the first reference layer 31, and a metal trace 35 is laminated between the first composite layer 33 and the second composite layer 34.

Still as shown in FIG. 4, the first composite layer 33 and the second composite layer 34 each include a first dielectric layer 301 and a second dielectric layer 302 that are disposed opposite to each other, the first dielectric layer 301 is in contact with the second dielectric layer 302, the first dielectric layer 301 is in contact with the metal trace 35, and stiffness of the second dielectric layer 302 is greater than stiffness of the first dielectric layer 301.

That is, different from a conventional arrangement of a single dielectric layer enclosing a metal trace, in the package substrate 200 provided in this embodiment of the present disclosure, the metal trace 35 is laminated between the first composite layer 33 and the second composite layer 34, and each composite layer includes the first dielectric layer 301 and the second dielectric layer 302 that are respectively made of two types of dielectrics. In both composite layers 33 and 34, the first dielectric layer 301 with relatively small stiffness is in contact with the metal trace 35 such that the metal trace 35 is enclosed by the first dielectric layers 301 using a lamination technique. The second dielectric layer 302 with relatively large stiffness is disposed on a side that is of the first dielectric layer 301 and away from the metal trace 35. The second dielectric layer 302 has relatively large stiffness and is not easy to deform. Therefore, a second dielectric layer with a relatively large thickness can be produced. In this case, for a high frequency signal or a high-speed signal, a conductor loss generated during signal transmission may be reduced by increasing a thickness of the second dielectric layer 302 in addition to increasing a width of the metal trace 35. This also ensures that impedance is consistent before and after the width of the metal trace 35 is changed, thereby reducing a link loss throughout the transmission.

Further, a dielectric loss factor of the first dielectric layer 301 is less than a dielectric loss factor of the second dielectric layer 302.

The dielectric loss factor may also be referred to as a dielectric loss tangent (Df). The Df is a complementary angle δ of an included angle (that is, a power vector angle Φ) between a current vector and a voltage vector passing through a dielectric under an alternating electric field, and can reflect a phase difference of electric displacement and electric field strength of the dielectric under the influence of the alternating electric field.

A smaller dielectric loss factor of a dielectric layer results in a smaller dielectric loss generated when a signal is being transmitted at the dielectric layer. In this case, in the package substrate 200 provided in this embodiment of the present disclosure, as shown in FIG. 4, when the dielectric loss factor of the first dielectric layer 301 is less than the dielectric loss factor of the second dielectric layer 302, a dielectric loss generated when a signal on the metal trace 35 is being transmitted at the first dielectric layer 301 can be reduced because the metal trace 35 is enclosed by the first dielectric layer 301 in the first composite layer 33 and the first dielectric layer 301 in the second composite layer 34. That is, the package substrate 200 provided in this embodiment of the present disclosure can not only reduce the conductor loss generated during signal transmission, but also reduce the dielectric loss generated during signal transmission.

Further, based on the package substrate 200 shown in FIG. 4, as shown in FIG. 5, the first composite layer 33 and the second composite layer 34 each further include a third dielectric layer 303 disposed on a side that is of the second dielectric layer 302 and away from the first dielectric layer 301, where a mechanical property of a material for fabricating the third dielectric layer 303 is the same as a mechanical property of a material for fabricating the first dielectric layer 301.

For example, a CTE of the material for fabricating the third dielectric layer 303 is the same as a CTE of the material for fabricating the first dielectric layer 301.

Optionally, the material of the third dielectric layer 303 may be the same as the material of the first dielectric layer 301.

In this case, the first composite layer 33 and the second composite layer 34 each can be regarded as a “sandwich structure” in which the first dielectric layer 301 and the third dielectric layer 303 sandwich the second dielectric layer 302. A reason for respectively disposing the first dielectric layer 301 and the third dielectric layer 303 with the same material on two sides of the second dielectric layer 302 is as follows. The stiffness of the second dielectric layer 302 is greater than the stiffness of the first dielectric layer 301, and when the second dielectric layer 302 is directly laminated with the first dielectric layer 301 to form the first composite layer 33 or the second composite layer 34, the first dielectric layer 301 with relatively small stiffness may be deformed. In this case, an unstable material structure in the first composite layer 33 or the second composite layer 34 leads to deformation of the first composite layer 33 or the second composite layer 34, and this increases difficulty of a technique for fabricating the first composite layer 33 and the second composite layer 34. However, when the first dielectric layer 301 and the third dielectric layer 303 with the same material are respectively disposed on the two sides of the second dielectric layer 302 for lamination, tension is generated on both a contact surface between the first dielectric layer 301 and the second dielectric layer 302 and a contact surface between the third dielectric layer 303 and the second dielectric layer 302. In this way, the first dielectric layer 301 and the third dielectric layer 303 are attached on the two sides of the second dielectric layer 302 such that a structurally stable “sandwich structure” is formed in each of the first composite layer 33 and the second composite layer 34, and more stable structures of the first composite layer 33 and the second composite layer 34 are formed.

Optionally, a thickness of the third dielectric layer 303 is equal to a thickness of the first dielectric layer 301.

For example, a CTE of the second dielectric layer 302 may be less than or equal to 9 ppm/° C.

For example, a Young's modulus of the second dielectric layer 302 may be greater than or equal to 25 MPa.

For example, the dielectric loss factor of the first dielectric layer 301 may be less than or equal to 0.01.

For example, the material for fabricating the first dielectric layer 301 and the third dielectric layer 303 may be a material, such as epoxy resin base, featuring high frequency and a low loss.

For example, a material for fabricating the second dielectric layer 302 may be a mixed material of a bismaleimide-triazine resin material and fiber glass cloth.

For example, the first reference layer 31 and the second reference layer 32 may be conductive metal plates.

Certainly, the foregoing is merely an example of a material selected for each component in the package substrate 200 provided in this embodiment of the present disclosure. A person skilled in the art may perform selection according to practical experience or an actual requirement. This is not limited in this embodiment of the present disclosure.

In addition, the package substrate 200 shown in FIG. 4 or FIG. 5 is described using only the first reference layer 31, the second reference layer 32, and the composite layers (that is, the first composite layer 33 and the second composite layer 34) between the two reference layers 31 and 32 as an example. It should be understood that the package substrate 200 may be formed by multiple reference layers and multiple composite layers that are stacked alternately, and a structure of the first composite layer 33 and the second composite layer 34 shown in FIG. 4 or FIG. 5 may be disposed between any two reference layers.

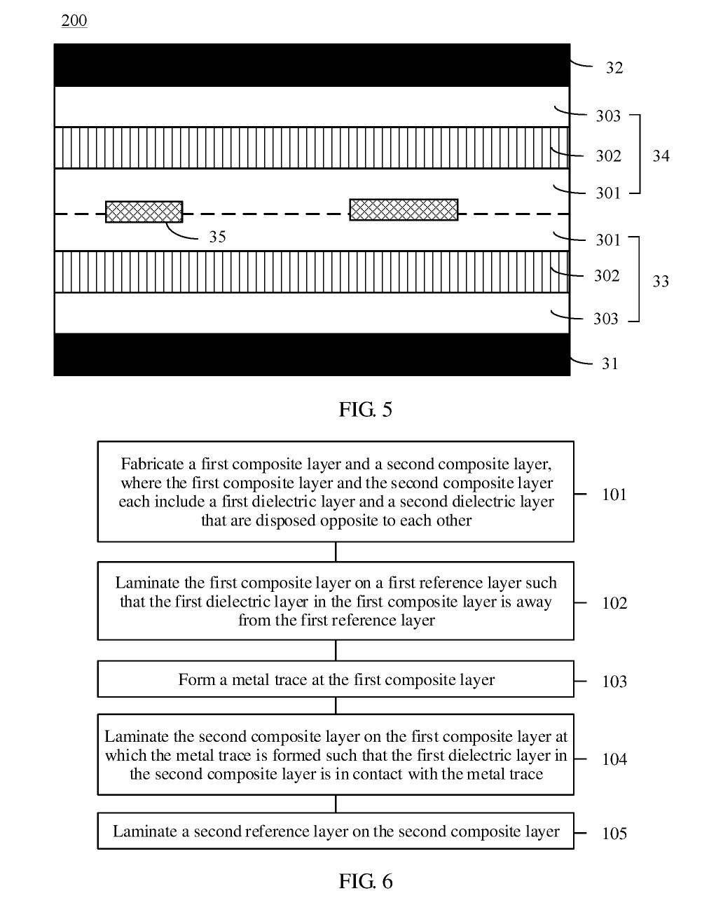

Further, based on the package substrate 200 shown in FIG. 4 or FIG. 5, an embodiment of the present disclosure provides a method for fabricating a package substrate. As shown in FIG. 6, the method includes the following steps.

Step 101: Fabricate a first composite layer and a second composite layer, where the first composite layer and the second composite layer each include a first dielectric layer and a second dielectric layer that are disposed opposite to each other.

Stiffness of the second dielectric layer is greater than stiffness of the first dielectric layer.

As shown in FIG. 4, the first dielectric layer 301 and the second dielectric layer 302 may be laminated using a lamination technique to form the first composite layer 33 or the second composite layer 34.

In addition, as shown in FIG. 5, the first composite layer 33 and the second composite layer 34 each may further include a third dielectric layer 303 disposed on a side that is of the second dielectric layer 302 and away from the first dielectric layer 301. A material of the third dielectric layer 303 is the same as a material of the first dielectric layer 301, and a thickness of the third dielectric layer 303 is equal to a thickness of the first dielectric layer 301. That is, the first dielectric layer 301, the second dielectric layer 302, and the third dielectric layer 303 form a “sandwich structure.”

In this case, during fabrication of the first composite layer 33 or the second composite layer 34, the second dielectric layer 302 may be used as an intermediate layer, and the first dielectric layer 301 and the third dielectric layer 303 are directly laminated onto two sides of the second dielectric layer 302 respectively.

Step 102: Laminate the first composite layer on a first reference layer such that the first dielectric layer in the first composite layer is away from the first reference layer.

Further, as shown in FIG. 7, the first composite layer 33 may be laminated onto the first reference layer 31 using the third dielectric layer 303 in the first composite layer 33 as a lamination surface such that the first dielectric layer 301 in the first composite layer 33 is away from the first reference layer 31.

A thickness of the second dielectric layer 302 may be set according to a width of a metal trace 35 such that impedance is consistent before and after the width of the metal trace 35 is changed. The width of the metal trace 35 may be set according to a speed or frequency of a signal that needs to be transmitted. When a speed or frequency of a transmitted signal is higher, the width of the metal trace 35 may be increased to reduce a conductor loss generated during signal transmission. Correspondingly, the thickness of the second dielectric layer 302 may be increased.

Step 103: Form a metal trace at the first composite layer.

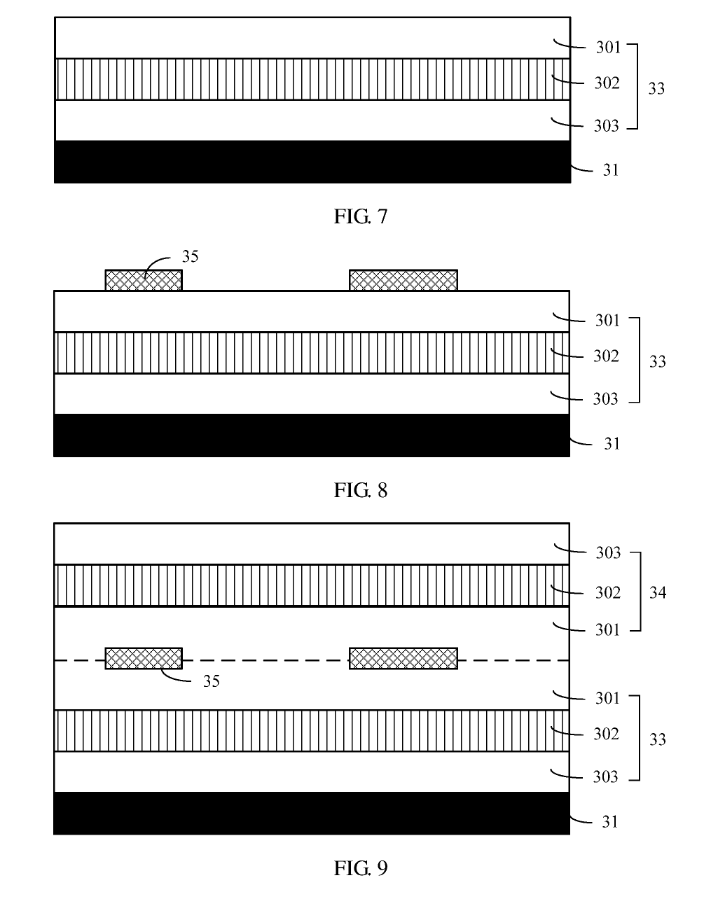

Further, as shown in FIG. 8, the metal trace 35 is formed at the first dielectric layer 301 in the first composite layer 33. The width of the metal trace 35 may also be set according to a speed or frequency of a signal.

Step 104: Laminate the second composite layer on the first composite layer at which the metal trace is formed such that the first dielectric layer in the second composite layer is in contact with the metal trace.

Further, as shown in FIG. 9, the second composite layer 34 may be laminated, using the first dielectric layer 301 in the second composite layer 34 as a lamination surface, onto the first composite layer 33 at which the metal trace 35 is formed. In this case, the metal trace 35 is enclosed by the first dielectric layers 301 in the first composite layer 33 and the second composite layer 34.

Step 105: Laminate a second reference layer on the second composite layer.

Finally, the second reference layer 32 is laminated on the third dielectric layer 303 in the second composite layer 34 to form the package substrate 200 shown in FIG. 5.

Alternatively, based on the package substrate 200 shown in FIG. 4 or FIG. 5, an embodiment of the present disclosure provides another method for fabricating a package substrate, that is directly performing lamination in a sequence of the first reference layer 31, the first composite layer 33, the metal trace 35, the second composite layer 34, and the second reference layer 32 in FIG. 4 or FIG. 5 in order to form the package substrate 200 in a one-off manner.

Alternatively, based on the package substrate 200 shown in FIG. 4 or FIG. 5, an embodiment of the present disclosure provides another method for fabricating a package substrate. Using the package substrate 200 shown in FIG. 4 as an example, the fabrication method includes laminating a second dielectric layer 302 of a first composite layer 33 on a first reference layer 31, laminating a first dielectric layer 301 of the first composite layer 33 on the second dielectric layer 302, where in this case, the first dielectric layer 301 and the second dielectric layer 302 constitute the first composite layer 33, laminating a metal trace 35 on the first dielectric layer 301 of the first composite layer 33, laminating another first dielectric layer 301, that is, a first dielectric layer 301 of a second composite layer 34, on the first dielectric layer 301 of the first composite layer 33, laminating another second dielectric layer 302, that is, a second dielectric layer 302 of the second composite layer 34, on the first dielectric layer 301 of the second composite layer 34, where in this case, the first dielectric layer 301 and the second dielectric layer 302 above the metal trace 35 constitute the second composite layer 34, and finally laminating a second reference layer 32 on the second dielectric layer 302 of the second composite layer 34 to form the package substrate 200.

An embodiment of the present disclosure further provides an IC chip, and the IC chip includes any one of the foregoing package substrates 200.

An embodiment of the present disclosure further provides a PCB, and the PCB includes any one of the foregoing package substrates 200.

Till now, the embodiments of the present disclosure provide a package substrate and a fabrication method thereof, an IC chip, and a PCB. The package substrate includes a first reference layer and a second reference layer that are disposed opposite to each other, a first composite layer is disposed on a side that is of the first reference layer and close to the second reference layer, a second composite layer is disposed on a side that is of the second reference layer and close to the first reference layer, and a metal trace is laminated between the first composite layer and the second composite layer. Further, the first composite layer and the second composite layer each include a first dielectric layer and a second dielectric layer that are disposed opposite to each other. In the first composite layer and the second composite layer, the first dielectric layer is in contact with the metal trace. Stiffness of the second dielectric layer is greater than stiffness of the first dielectric layer. It can be learned that in both composite layers, the first dielectric layer with relatively small stiffness is in contact with the metal trace such that the metal trace is enclosed by the first dielectric layers using a lamination technique. The second dielectric layer with relatively large stiffness is disposed on a side that is of the first dielectric layer and away from the metal trace. That is, the second dielectric layer is not easy to deform. Therefore, a second dielectric layer with a relatively large thickness can be produced. In this case, for a high frequency signal or a high-speed signal, to reduce a conductor loss generated during signal transmission as much as possible, a thickness of the second dielectric layer may be increased in addition to increasing a width of the metal trace. This further reduces a link loss throughout the transmission.

A person skilled in the art should be aware that in the foregoing one or more examples, functions described in the present disclosure may be implemented by hardware, software, firmware, or any combination thereof. When the present disclosure is implemented by software, the foregoing functions may be stored in a computer-readable medium or transmitted as one or more instructions or code in the computer-readable medium. The computer-readable medium includes a computer storage medium and a communications medium, where the communications medium includes any medium that enables a computer program to be transmitted from one place to another. The storage medium may be any available medium accessible to a general-purpose or dedicated computer.

The objectives, technical solutions, and benefits of the present disclosure are further described in detail in the foregoing specific embodiments. It should be understood that the foregoing descriptions are merely specific embodiments of the present disclosure, but are not intended to limit the protection scope of the present disclosure. Any modification, equivalent replacement, or improvement made within the spirit and principle of the present disclosure shall fall within the protection scope of the present disclosure.

What is claimed is:

1. A package substrate, comprising:
a first reference layer;
a second reference layer disposed opposite to the first reference layer;
a first composite layer disposed on a side of the first reference layer and proximate to the second reference layer;
a second composite layer disposed on a side of the second reference layer and proximate to the first reference layer; and
a metal trace laminated between the first composite layer and the second composite layer,
wherein the first composite layer and the second composite layer each comprise a first dielectric layer and a second dielectric layer disposed opposite to and in contact with each other,
wherein the first dielectric layer is in contact with the metal trace, and
wherein a stiffness of the second dielectric layer is greater than a stiffness of the first dielectric layer.

2. The package substrate according to claim 1, wherein a dielectric loss factor of the first dielectric layer is less than a dielectric loss factor of the second dielectric layer.

3. The package substrate according to claim 1, wherein the first composite layer and the second composite layer each further comprise a third dielectric layer disposed on a side of the second dielectric layer and away from the first dielectric layer, and wherein a mechanical property of a material of the third dielectric layer is the same as a mechanical property of a material of the first dielectric layer.

4. The package substrate according to claim 3, wherein the material of the third dielectric layer is the same as the material of the first dielectric layer, and wherein a thickness of the third dielectric layer is equal to a thickness of the first dielectric layer.

5. The package substrate according to claim 1, wherein a coefficient of thermal expansion (CTE) of the second dielectric layer is less than 9 parts per million (ppm)/degree Celsius (° C.).

6. The package substrate according to claim 1, wherein a coefficient of thermal expansion (CTE) of the second dielectric layer is equal to 9 parts per million (ppm)/degree Celsius (° C.).

7. The package substrate according to claim 1, wherein a Young's modulus of the second dielectric layer is greater than 25 megapascals (MPa).

8. The package substrate according to claim 1, wherein a Young's modulus of the second dielectric layer is equal to 25 megapascals (MPa).

9. A method for fabricating a package substrate, comprising:
laminating a first composite layer on a first reference layer, wherein the first composite layer comprises a first dielectric layer and a second dielectric layer disposed opposite to each other, wherein a stiffness of the second dielectric layer is greater than a stiffness of the first dielectric layer, and wherein the first dielectric layer in the first composite layer is away from the first reference layer;
forming a metal trace at the first composite layer;
laminating a second composite layer on the first composite layer at which the metal trace is formed, wherein the second composite layer comprises the first dielectric layer and the second dielectric layer disposed opposite to each other, and wherein the first dielectric layer in the second composite layer is in contact with the metal trace; and
laminating a second reference layer on the second composite layer.

10. The method according to claim 9, wherein before laminating the first composite layer on the first reference layer, the method further comprises fabricating the first composite layer and the second composite layer.

11. The method according to claim 10, wherein the first composite layer and the second composite layer each further comprise a third dielectric layer disposed on a side of the second dielectric layer and away from the first dielectric layer, wherein a material of the third dielectric layer is the same as a material of the first dielectric layer, and wherein fabricating the first composite layer comprises respectively laminating the first dielectric layer and the third dielectric layer onto two sides of the second dielectric layer to obtain the first composite layer.

12. The method according to claim 10, wherein the first composite layer and the second composite layer each further comprise a third dielectric layer disposed on a side of the second dielectric layer and away from the first dielectric layer, wherein a material of the third dielectric layer is the same as a material of the first dielectric layer, and wherein fabricating the second composite layer comprises respectively laminating the first dielectric layer and the third dielectric layer onto two sides of the second dielectric layer to obtain the second composite layer.

13. The method according to claim 11, wherein laminating the first composite layer on the first reference layer comprises laminating the first composite layer onto the first reference layer using the third dielectric layer in the first composite layer as a lamination surface, and wherein laminating the second composite layer on the first composite layer at which the metal trace is formed comprises laminating, using the first dielectric layer in the second composite layer as another lamination surface, the second composite layer onto the first composite layer at which the metal trace is formed.

14. The method according to claim 12, wherein laminating the first composite layer on the first reference layer comprises laminating the first composite layer onto the first reference layer using the third dielectric layer in the first composite layer as a lamination surface, and wherein laminating the second composite layer on the first composite layer at which the metal trace is formed comprises laminating, using the first dielectric layer in the second composite layer as another lamination surface, the second composite layer onto the first composite layer at which the metal trace is formed.

15. A method for fabricating a package substrate, comprising performing one-off lamination in a sequence of a first reference layer, a first composite layer, a metal trace, a second composite layer, and a second reference layer in order to form the package substrate, wherein the first composite layer and the second composite layer each comprise a first dielectric layer and a second dielectric layer disposed opposite to each other, wherein the first dielectric layer is in contact with the metal trace, and wherein a stiffness of the second dielectric layer is greater than a stiffness of the first dielectric layer.

16. An integrated circuit (IC) chip, comprising a package substrate comprising:
a first reference layer;
a second reference layer disposed opposite to the first reference layer;
a first composite layer disposed on a side of the first reference layer and proximate to the second reference layer;
a second composite layer disposed on a side of the second reference layer and proximate to the first reference layer; and
a metal trace laminated between the first composite layer and the second composite layer,
wherein the first composite layer and the second composite layer each comprise a first dielectric layer and a second dielectric layer disposed opposite to and in contact with each other,
wherein the first dielectric layer is in contact with the metal trace, and
wherein a stiffness of the second dielectric layer is greater than a stiffness of the first dielectric layer.
